(19) United States
(12) Patent Application Publication
(10) Pub. No.: US 2025/0057048 A1
(43) Pub. Date: Feb. 13, 2025

(54) PIEZOELECTRIC LAMINATE, PIEZOELECTRIC ELEMENT, AND PRODUCTION METHOD FOR PIEZOELECTRIC LAMINATE

(71) Applicant: AGC Inc., Tokyo (JP)

(72) Inventors: Kenichi UMEDA, Tokyo (JP); Akiyo NOGAMI, Tokyo (JP); Masafumi AKITA, Tokyo (JP)

(73) Assignee: AGC Inc., Tokyo (JP)

(21) Appl. No.: 18/929,698

(22) Filed: Oct. 29, 2024

Related U.S. Application Data
(63) Continuation of application No. PCT/JP2023/016981, filed on Apr. 28, 2023.

(30) Foreign Application Priority Data
May 16, 2022 (JP) 2022-080483

(51) Int. Cl. H10N 30/00; H10N 30/076; H10N 30/079; H10N 30/853

(52) U.S. Cl. CPC H10N 30/708; H10N 30/076; H10N 30/079; H10N 30/853

(57) ABSTRACT

The present invention relates to a piezoelectric laminated body including: a substrate; and a laminated film provided on at least one surface of the substrate, in which the laminated film includes an electrode layer, a base layer, and a piezoelectric thin film in this order from a substrate side, the base layer and the piezoelectric thin film are in contact with each other, the base layer contains zirconium nitride, and the piezoelectric thin film has a hexagonal wurtzite structure oriented in a c-axis direction.

### TECHNICAL FIELD

The present invention relates to a piezoelectric laminated body, a piezoelectric element, and a method of manufacturing a piezoelectric laminated body.

### BACKGROUND ART

In recent years, micro electro mechanical systems (MEMS) have attracted attention. The MEMS is a device in which mechanical element components, electronic circuits, and the like are integrated on a single substrate by a micromachining technique. In MEMS having functions of a sensor, a filter, a harvester, an actuator, or the like, a piezoelectric laminated body is used.

It is known that a piezoelectric laminated body is formed by providing aluminum nitride (AlN), which is a substance having a hexagonal wurtzite structure, on a substrate such as silicon (Si) or sapphire or a glass substrate. The aluminum nitride has piezoelectric properties and pyroelectric properties in a c-axis direction. Therefore, an aluminum nitride thin film, that is, a c-axis oriented aluminum nitride thin film is applied as a piezoelectric thin film resonator, a component of MEMS, or the like by utilizing the piezoelectric properties thereof. In addition, the aluminum nitride thin film is applied as a sensor or the like by utilizing the pyroelectric properties thereof.

As described above, many studies have been made to obtain an aluminum nitride thin film having high c-axis orientation. For example, Patent Literatures 1 and 2 disclose that c-axis orientation is improved by providing a base layer of tungsten or platinum between a silicon substrate or a glass substrate and aluminum nitride. Patent Literature 3 discloses that good crystallinity can be obtained by using an aluminum nitride base layer having a crystal of the same hexagonal wurtzite structure.

### CITATION LIST

### Patent Literature

Patent Literature 1: JP2004-6535A
Patent Literature 2: JP2004-265899A
Patent Literature 3: JP2019-145677A

### SUMMARY OF INVENTION

### Technical Problem

However, in order to improve crystalline orientation by a method in the related art, an electrode layer in contact with a piezoelectric thin film has the same crystal structure, or lattice matching is required, and there is a limitation on selection of an electrode material constituting the electrode layer.

Therefore, an object of the present invention is to eliminate an influence of the crystal structure and lattice matching of the piezoelectric thin film and the electrode layer and improve crystalline orientation of the piezoelectric thin film.

### Solution to Problem

The present inventors have found that the above problem can be solved by providing a base layer containing zirconium nitride between the piezoelectric thin film and the electrode layer, and have completed the present invention.

That is, an embodiment of the present invention relates to the following.

[1]A piezoelectric laminated body including:
a substrate; and
a laminated film provided on at least one surface of the substrate, in which
the laminated film includes an electrode layer, a base layer, and a piezoelectric thin film in this order from a substrate side,
the base layer and the piezoelectric thin film are in contact with each other,
the base layer contains zirconium nitride, and
the piezoelectric thin film has a hexagonal wurtzite structure oriented in a c-axis direction.

[2] The piezoelectric laminated body according to [1], in which the piezoelectric thin film contains aluminum nitride, and the aluminum nitride has the hexagonal wurtzite structure oriented in the c-axis direction.

[3] The piezoelectric laminated body according to [1], in which the zirconium nitride is represented by a chemical formula ZrN_{X}, and a nitriding degree represented by x in the chemical formula is in a range of 0<x<2.

[4] The piezoelectric laminated body according to [3], in which the nitriding degree is in a range of 1<x<2.

[5] The piezoelectric laminated body according to [1], in which a thickness of a base film is 0.2 nm or more and 40 nm or less.

[6] The piezoelectric laminated body according to [5], in which the thickness of the base film is 0.4 nm or more and 20 nm or less.

[7] The piezoelectric laminated body according to [1], in which an arithmetic average roughness (Ra) of the piezoelectric thin film is 4.0 nm or less.

[8] The piezoelectric laminated body according to [1], in which a ratio {(101) plane/(002) plane} of a peak intensity of a (101) plane to a peak intensity of a (002) plane in an X-ray diffraction pattern of the piezoelectric thin film measured by an out-of-plane method is 0.25 or less.

[9] The piezoelectric laminated body according to [1], in which a ratio {(101) plane/(002) plane} of a peak intensity of a (101) plane to a peak intensity of a (002) plane in an X-ray diffraction pattern of the piezoelectric thin film measured by an out-of-plane method is 0.1 or less.

[10] The piezoelectric laminated body according to [1], in which a film thickness of the piezoelectric thin film is 100 nm or more and 10 μm or less.

[11]A piezoelectric element including the piezoelectric laminated body according to any of [1] to [10].

[12]A method for manufacturing a piezoelectric laminated body including a substrate and a laminated film provided on at least one surface of the substrate, the method including:
preparing the substrate; and
forming an electrode layer, a base layer, and a piezoelectric thin film on the at least one surface of the substrate in this order, in which
the base layer contains zirconium nitride,
the piezoelectric thin film has a hexagonal wurtzite structure oriented in a c-axis direction, and
the piezoelectric thin film is formed so as to be in contact with the base layer.

[13] The method for manufacturing a piezoelectric laminated body according to [12], in which the piezoelectric thin film contains aluminum nitride, and
the aluminum nitride has the hexagonal wurtzite structure oriented in the c-axis direction.

[14] The method for manufacturing a piezoelectric laminated body according to [12] or [13], in which a film formation is performed by a sputtering method.

Another embodiment of the present invention relates to the following.

[1]′ A piezoelectric laminated body including:
a substrate; and
a laminated film provided on at least one surface of the substrate, in which
the laminated film includes an electrode layer, a base layer, and a piezoelectric thin film in this order from a substrate side,
the base layer and the piezoelectric thin film are in contact with each other,
the base layer contains zirconium nitride, and
the piezoelectric thin film has a hexagonal wurtzite structure oriented in a c-axis direction.

[2]′ The piezoelectric laminated body according to [1]′, in which the piezoelectric thin film contains aluminum nitride, and
the aluminum nitride has the hexagonal wurtzite structure oriented in the c-axis direction.

[3]′ The piezoelectric laminated body according to [1]′ or [2]′, in which the zirconium nitride is represented by a chemical formula ZrN_{X}, and a nitriding degree represented by x in the chemical formula is in a range of 0<x<2.

[4]′ The piezoelectric laminated body according to [3]′, in which the nitriding degree is in a range of 1<x<2.

[5]′ The piezoelectric laminated body according to any of [1]′ to [4]′, in which a thickness of a base film is 0.2 nm or more and 40 nm or less.

[6]′ The piezoelectric laminated body according to [5]′, in which the thickness of the base film is 0.4 nm or more and 20 nm or less.

[7]′ The piezoelectric laminated body according to any of [1]′ to [6]′, in which an arithmetic average roughness (Ra) of the piezoelectric thin film is 4.0 nm or less.

[8]′ The piezoelectric laminated body according to any of [1]′ to [7]′, in which a ratio {(101) plane/(002) plane} of a peak intensity of a (101) plane to a peak intensity of a (002) plane in an X-ray diffraction pattern of the piezoelectric thin film measured by an out-of-plane method is 0.25 or less.

[9]′ The piezoelectric laminated body according to any of [1]′ to [8]′, in which a ratio {(101) plane/(002) plane} of a peak intensity of a (101) plane to a peak intensity of a (002) plane in an X-ray diffraction pattern of the piezoelectric thin film measured by an out-of-plane method is 0.1 or less.

[10]′ The piezoelectric laminated body according to any of [1]′ to [9]′, in which a film thickness of the piezoelectric thin film is 100 nm or more and 10 μm or less.

[11]′ A piezoelectric element including the piezoelectric laminated body according to any of [1]′ to [10]′.

[12]′ A method for manufacturing a piezoelectric laminated body including a substrate and a laminated film provided on at least one surface of the substrate, the method including:
preparing the substrate; and
forming an electrode layer, a base layer, and a piezoelectric thin film on the at least one surface of the substrate in this order, in which
the base layer contains zirconium nitride,
the piezoelectric thin film has a hexagonal wurtzite structure oriented in a c-axis direction, and
the piezoelectric thin film is formed so as to be in contact with the base layer.

[13]′ The method for manufacturing a piezoelectric laminated body according to [12]′, in which the piezoelectric thin film contains aluminum nitride, and
the aluminum nitride has the hexagonal wurtzite structure oriented in the c-axis direction.

[14]′ The method for manufacturing a piezoelectric laminated body according to [12]′ or [13]′, in which a film formation is performed by a sputtering method.

### Advantageous Effects of Invention

According to the present invention, it is possible to eliminate an influence of the crystal structure and lattice matching of the piezoelectric thin film and the electrode layer and improve crystalline orientation of the piezoelectric thin film.

### BRIEF DESCRIPTION OF DRAWINGS

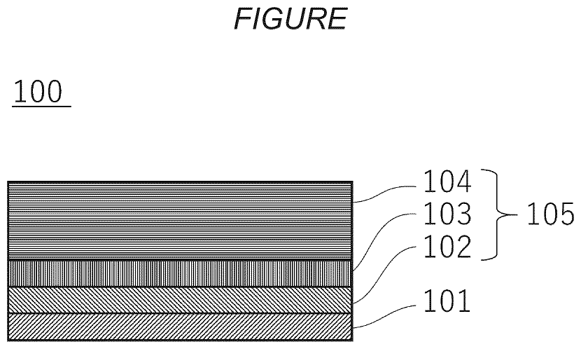

The FIG. 1s a schematic cross-sectional view of a piezoelectric laminated body according to the present embodiment.

### DESCRIPTION OF EMBODIMENTS

Hereinafter, a content of an embodiment of the present invention will be described with reference to the drawing. However, the present invention includes many different aspects, and should not be construed as being limited to the content of the embodiment exemplified below.

### <Piezoelectric Laminated Body>

A structure and a manufacturing method of a piezoelectric laminated body 100 according to the present embodiment will be described with reference to the FIGURE.

### [Structure of Piezoelectric Laminated Body]

The FIG. 1s a schematic cross-sectional view illustrating the structure of the piezoelectric laminated body 100 according to the present embodiment. As illustrated in the FIGURE, the piezoelectric laminated body 100 includes a substrate 101 and a laminated film 105 provided on at least one surface of the substrate 101. The laminated film 105 includes an electrode layer 102, a base layer 103, and a piezoelectric thin film 104 in this order from a substrate side. Here, the base layer 103 and the piezoelectric thin film 104 are in contact with each other.

### (Substrate)

A thickness, a material, and the like of the substrate 101 are not particularly limited as long as the laminated film 105 can be formed on the surface of the substrate 101, and any conventionally known material can be used.

As the substrate 101, for example, a silicon (Si) single crystal, or a substrate obtained by forming silicon, diamond, or another polycrystalline film on a surface of a base material such as a Si single crystal can be used. As the substrate 101, a metal substrate of stainless steel (SUS or the like), an amorphous substrate of glass or the like, or a film of polyethylene terephthalate (PET) or the like can be used.

### (Electrode Layer)

The electrode layer 102 is not particularly limited, and an electrode layer commonly used for the piezoelectric laminated body 100 can be used.

As an electrode material constituting the electrode layer 102, for example, a film containing a metal material such as aluminum (Al), a transition metal such as molybdenum (Mo), titanium (Ti), chromium (Cr), tantalum (Ta), iridium (Ir), or nickel (Ni), a noble metal such as ruthenium (Ru), palladium (Pd), platinum (Pt), gold (Au), silver (Ag), or copper (Cu), a conductive metal oxide such as ruthenium oxide (RuO₂), or a conductive metal nitride such as chromium nitride (CrN) is used. In addition, the above materials may be combined to form the electrode layer 102.

A film thickness of the electrode layer 102 is not particularly limited, and is preferably 5 nm to 1,000 nm, for example. Here, from the viewpoint of forming a continuous film, the above film thickness is preferably 5 nm or more. In addition, from the viewpoint of preventing the continuous film from being lost due to generation of cracks or the like, the above film thickness is preferably 1,000 nm or less.

An arithmetic average roughness (Ra) of the electrode layer 102 is not particularly limited, and is preferably 0.1 nm to 10 nm, for example. Here, from the viewpoint of obtaining good electrical conductivity due to presence of crystal grains, the above arithmetic average roughness (Ra) is preferably 0.1 nm or more. In addition, from the viewpoint of preventing a reduction in electrical conductivity due to grain boundary scattering, the above arithmetic average roughness (Ra) is preferably 10 nm or less.

A specific electrical resistance of the electrode layer 102 is preferably 1×10⁻⁶ Ω·cm to 1×10⁻² Ω·cm. Here, from the viewpoint of ensuring good conductivity, the above specific electrical resistance is preferably 1×10⁻² Ω·cm or less, and particularly preferably 1×10⁻³ Ω·cm or less. A lower limit of the above specific electrical resistance is not particularly limited, and is usually 1×10⁻⁶ Ω·cm or more.

### (Base Layer)

The base layer 103 is a layer formed directly or via another layer on the electrode layer 102, and improves crystalline orientation of the piezoelectric thin film 104 provided on the base layer 103. The base layer 103 is in direct contact with the piezoelectric thin film 104.

It is known that the crystalline orientation of the piezoelectric thin film 104 is greatly affected by a surface of a layer on which the piezoelectric thin film 104 is provided.

In contrast, the present inventors have found that the crystalline orientation is improved in a case where the piezoelectric thin film 104 has a hexagonal wurtzite structure oriented in a c-axis direction when the base layer 103 containing zirconium nitride is provided and the piezoelectric thin film 104 is directly provided thereon. Among those, when the piezoelectric thin film 104 is a film containing aluminum nitride having a hexagonal wurtzite structure oriented in the c-axis direction, the c-axis orientation of the piezoelectric thin film 104 can be particularly improved.

The base layer 103 contains zirconium nitride. The zirconium nitride is represented by a chemical formula ZrN_{X}, and in the chemical formula, x represents a nitriding degree. The nitriding degree x is more than 0, and is preferably more than 0 and less than 2. Here, the nitriding degree x is preferably more than 1, more preferably more than 1.1, and is preferably less than 2, more preferably less than 1.65. Within the above range, the c-axis orientation of the piezoelectric thin film 104 is further improved. This effect is remarkable when the piezoelectric thin film 104 contains aluminum nitride.

The nitriding degree x can be identified by Rutherford backscattering spectrometry (RBS). Further, in a case where there are a plurality of samples, the nitriding degree x for two or more samples may be measured by the above RBS method and ellipsometry, respectively, and a correlation coefficient thereof is derived, and thereafter, the nitriding degree x by the RBS method for other samples may be calculated based on a measurement result by ellipsometry.

A thickness of the base layer 103 is not particularly limited, and is preferably 0.1 nm to 100 nm. Here, from the viewpoint of further enhancing the c-axis orientation of the piezoelectric thin film 104, the above thickness is preferably 0.1 nm or more, more preferably 0.2 nm or more, further preferably 0.4 nm or more, and is preferably 100 nm or less, more preferably 40 nm or less, particularly preferably 20 nm or less.

### (Piezoelectric Thin Film)

The piezoelectric thin film 104 has a hexagonal wurtzite structure oriented in the c-axis direction. The provision of the hexagonal wurtzite structure can be confirmed by, for example, an X-ray diffraction (XRD) method, an X-ray absorption spectroscopy (XAFS, EXAFS) method, or the like.

In addition, a crystalline orientation in which piezoelectric properties of the piezoelectric thin film 104 having the hexagonal wurtzite structure are exhibited is a [002] direction of the hexagonal wurtzite structure. That is, the piezoelectric thin film 104 can achieve excellent piezoelectric properties by a (002) plane of the hexagonal wurtzite structure being oriented (c-axis oriented).

In the present description, “oriented in the c-axis direction” and “c-axis oriented” mean that a peak intensity ratio of (101) plane/(002) plane in an X-ray diffraction pattern of the piezoelectric thin film measured by an out-of-plane method is less than 0.3.

The piezoelectric thin film 104 is a layer having at least one of piezoelectric properties and pyroelectric properties, and is a crystalline thin film having a hexagonal wurtzite structure oriented in the c-axis direction.

As the piezoelectric thin film 104, for example, a thin film of aluminum nitride (AlN), ZnO, GaN, or the like is preferably used. Among those, from the viewpoint of manufacturability and the viewpoint of improving the crystallinity of the base layer to be described later, it is particularly preferable that the thin film contains AlN, and it is more preferable that the thin film has a hexagonal wurtzite structure in which AlN is oriented in the c-axis direction.

The piezoelectric thin film 104 is preferably 0.1 nm to 5.5 nm. Here, the piezoelectric thin film 104 preferably has high smoothness, and preferably has a small arithmetic average roughness (Ra). An arithmetic average roughness (Ra) of a surface of the piezoelectric thin film 104 is preferably 5.5 nm or less, more preferably 5.0 nm or less, further preferably 4.0 nm or less, and particularly preferably 3.5 nm or less. In addition, a lower limit of the above arithmetic average roughness (Ra) is not particularly limited, and is preferably 0.1 nm or more, further preferably 0.2 nm or more, and most preferably 0.3 nm or more from the viewpoint of adhesion during formation of the laminated film.

The arithmetic average roughness (Ra) of the surface of the piezoelectric thin film is an arithmetic average roughness of a surface on a side in contact with the base layer 103. The arithmetic average roughness (Ra) is measured by an atomic force microscope (AFM).

The film thickness of the piezoelectric thin film 104 is not particularly limited, and is preferably 100 nm to 10 μm. Here, from the viewpoint of ensuring good crystalline orientation and sufficiently ensuring piezoelectric properties, the above film thickness is preferably 100 nm or more, more preferably 250 nm or more, further preferably 500 nm or more, and most preferably 1 μm or more. On the other hand, from the viewpoint of crystal growth without generating cracks, the film thickness is preferably 10 μm or less, further preferably 7.5 μm or less, and most preferably 5 μm or less.

The piezoelectric thin film 104 preferably has a peak intensity ratio {(101) plane/(002) plane} of the (101) plane and the (002) plane of 0 to 0.25 in the X-ray diffraction pattern measured by the out-of-plane method. Here, from the viewpoint of further ensuring the hexagonal wurtzite structure oriented in the c-axis direction and sufficiently ensuring the piezoelectric properties, the above peak intensity ratio is preferably 0.25 or less, more preferably 0.1 or less, further preferably 0.05 or less, and most preferably 0.01 or less. A lower limit of the above peak intensity ratio is not particularly limited and may be 0.

The piezoelectric laminated body according to the present embodiment may include a layer other than the above substrate, electrode layer, base layer, and piezoelectric thin film as long as the effect of the present invention is not impaired.

For example, an adhesion layer for adhering the substrate and a metal may be provided between the substrate and the electrode layer, and an adhesion layer for adhering the electrode and the base layer may be provided between the electrode layer and the base layer. In addition, at least one surface of the substrate may have a thermal oxide film. Further, an upper electrode layer or a protective layer may be provided on a surface opposite to that on an electrode layer side. Any of the above layers may be a known layer in the related art.

The piezoelectric laminated body according to the present embodiment can be suitably used for a piezoelectric element. The piezoelectric element can be suitably used not only for an element utilizing a piezoelectric effect such as a gyro sensor, a shock sensor, or a microphone, but also for an element utilizing an inverse piezoelectric effect such as an actuator, an inkjet head, a speaker, a buzzer, or a resonator.

### [Method of Manufacturing Piezoelectric Laminated Body]

The method of manufacturing a piezoelectric laminated body according to the present embodiment includes: preparing a substrate; and forming an electrode layer, a base layer, and a piezoelectric thin film in this order on at least one surface of the above substrate.

The base layer contains zirconium nitride, and the piezoelectric thin film has a hexagonal wurtzite structure oriented in the c-axis direction. The above piezoelectric thin film is formed in contact with the base layer.

As each of the above substrate, electrode layer, base layer, and piezoelectric thin film, the substrate, the electrode layer, the base layer, and the piezoelectric thin film described in the above [structure of piezoelectric laminated body] can be used. In addition, the piezoelectric laminated body to be obtained is preferably the piezoelectric laminated body described in the above [structure of piezoelectric laminated body].

That is, in the piezoelectric laminated body obtained by the manufacturing method according to the present embodiment, the base layer and the piezoelectric thin film are in contact with each other, the base layer contains zirconium nitride, and the piezoelectric thin film has a hexagonal wurtzite structure oriented in the c-axis direction.

### (Preparation of Substrate)

As the substrate, for example, the above-described substrate can be used, but a commercially available substrate or a prepared substrate may be used.

### (Formation of Laminated Film)

The laminated film 105 is formed on at least one surface of the substrate prepared above. The laminated film 105 is formed in the order of the electrode layer, the base layer, and the piezoelectric thin film, and for example, a physical vapor deposition method, a chemical vapor deposition method (CVD method), or the like can be adopted for any of those. Examples of the physical vapor deposition method include a physical vapor deposition method, a PVD method, and a sputtering method. Among those, the sputtering method is particularly preferable from the viewpoint of being able to control a doping amount in a wide range, and a magnetron sputtering method and a digital sputtering method are particularly preferable.

The electrode layer may be provided directly on at least one surface of the substrate or may be provided thereon via an adhesion layer or the like. The electrode layer may be a single layer or two or more layers.

The base layer may be provided directly on the electrode layer or may be provided thereon via an adhesion layer or the like.

Although the base layer contains zirconium nitride, in a case where the base layer is formed by a sputtering method, a composition of zirconium nitride ZrN_{X}, that is, a value of the nitriding degree x can be adjusted by controlling film formation conditions thereof. The film formation conditions include, for example, a temperature of the substrate 100 during film formation, a film formation pressure, a composition of an introduced gas, a target composition, and a post-heat treatment temperature.

The zirconium nitride ZrN_{X} constituting the base layer may contain impurities such as carbon and oxygen inevitably introduced during film formation at a maximum of about 10 at % (atoms %). In the case where the sputtering method is used, a maximum of about 10 at % of impurities contained in a target is allowed. That is, impurities contained in a target containing Zr, which is a target of zirconium nitride ZrN_{X} constituting the base layer, and Al, which is a target of a material constituting the piezoelectric thin film, for example, in a case where the material is aluminum nitride AlN, include Hf, Ti, Sc, V, Nb, Ta, Cr, Mo, W, O, C, and the like.

When the base layer is formed, the piezoelectric thin film may contain a doping element within a range in which the hexagonal wurtzite structure can be maintained. For example, in a case where the piezoelectric thin film contains aluminum nitride, by containing elements such as Sc, Y, Mg, Ca, Sr, Zr, Hf, V, and Nb as doping elements, strain is applied to aluminum nitride, and piezoelectric performance is improved. Particularly, the Sc element is preferable for improving the piezoelectric performance, and can be doped up to about 43 at % in this case.

The nitriding degree x of zirconium nitride ZrN_{X} in the base layer can be adjusted by a flow rate of nitrogen gas during film formation. For example, in a case where the nitriding degree x is adjusted to be in a range of 0<x<2, the flow rate of nitrogen gas is preferably 20% or more, particularly preferably 40% or more, in terms of a ratio of {N₂/(Ar+N₂)}. Further, even in a case where the above ratio is 100%, an amount of nitrogen can be adjusted to a larger amount by increasing the film formation pressure by increasing a flow rate of nitrogen, and the nitriding degree x can be set to a value close to 2.

The film formation pressure is preferably 0.05 Pa to 10 Pa. Here, from the viewpoint of crystal density and orientation, the above film formation pressure is preferably 0.05 Pa or more, more preferably 0.1 Pa or more, and is preferably 10 Pa or less, more preferably 1 Pa or less.

A substrate temperature during film formation of the base layer is preferably room temperature to 600° C. or less, and further preferably 250° C. or less.

In order to sufficiently exhibit an effect of the base layer, it is preferable to continuously perform film formation without breaking a vacuum state not only during formation of the base layer but also before forming all of the electrode layer, the base layer, and the piezoelectric thin film. In particular, when the vacuum state is broken when the base layer and the piezoelectric thin film are formed, oxygen may be mixed into the base layer as an impurity, and properties of the base layer may not be utilized. In this case, since good interface properties cannot be obtained, it is preferable to continuously perform film formation in a vacuum state.

The piezoelectric thin film is directly formed on the base layer.

The piezoelectric thin film can be formed by a known method in the related art using a known material in the related art as long as it is a thin film having a hexagonal wurtzite structure oriented in the c-axis direction.

For example, in a case of a thin film of aluminum nitride having a hexagonal wurtzite structure oriented in the c-axis direction, film formation conditions in a case of film formation by the sputtering method can be, for example, a pressure of 0.05 Pa to 10 Pa, a nitrogen gas partial pressure ratio of 20% to 100%, and a substrate temperature of 25° C. to 200° C.

### EXAMPLES

Hereinafter, the present invention is described in detail with reference to Examples, but the present invention is not limited thereto.

Example 1 to Example 21 are inventive examples, and Example 22 to Example 28 are comparative examples.

### Example 1

A soda-lime glass of 100 mm×100 mm×2 mmt was used as a substrate. An electrode layer was provided on one surface of the above substrate by the following procedure. As the electrode layer, only one layer of Ti of a lower electrode layer was formed.

The lower electrode layer was formed after placing the substrate in a vacuum chamber of a sputtering device, then evacuating the vacuum chamber, and lowering an air pressure to 10⁻³ Pa or less.
Film formation device: vertical in-line magnetron sputter (manufactured by ULVAC, Inc.)
Sputtering target material: Ti metal (purity: 3N, manufactured by Kojundo Chemical Laboratory Co., Ltd.)
Introduced gas: argon gas (purity=99.9% or more) 80 sccm
Film formation pressure: 0.4 Pa
Film thickness: 150 nm
Substrate heating temperature: room temperature

Subsequently, zirconium nitride (ZrN_{X}) was prepared as a base layer on the electrode layer by a sputtering method under the following conditions.

The formation of the base layer was performed under the following conditions after placing a sample on which the electrode layer was formed obtained as described above in the vacuum chamber of the sputtering device without breaking the vacuum from the formation of the electrode layer, then evacuating the vacuum chamber, and lowering the air pressure to 10⁻³ Pa or less.

The formation of the base layer was performed by the same device as the device for forming the lower electrode layer.
Sputtering target material: Zr metal (purity 2N2 (value including Hf), manufactured by Tanaka Kikinzoku Kogyo K.K.)
Introduced gas: nitrogen gas (purity=99.9% or more) 80 sccm
Film formation pressure: 0.4 Pa
Film thickness: 10 nm
Substrate heating temperature: room temperature

Next, aluminum nitride (AlN) was prepared as a piezoelectric thin film on the base layer by the following procedure.

Formation of the piezoelectric thin film was performed after lowering the air pressure to 10⁻³ Pa or less without breaking the vacuum from the formation of the base layer.

The formation of the piezoelectric thin film was performed by the same device as the device for forming the lower electrode layer and the base layer.
Sputtering target material: Al metal (3N), manufactured by Kojundo Chemical Laboratory Co., Ltd.
Introduced gas: mixed gas of 40 sccm of nitrogen gas (purity=99.9% or more) and 40 sccm of argon gas (purity=99.9% or more)
Mixing Ratio of N₂/(Ar+N₂): 0.5
Film formation pressure: 0.4 Pa
Substrate heating temperature: room temperature
Film thickness: 1 μm

In this manner, a piezoelectric laminated body was obtained in which a lower electrode, a ZrN_{X} film as the base layer, and aluminum nitride (AlN) as the piezoelectric thin film were formed in this order on the substrate.

### Examples 2 to 6

In Examples 2 to 6, piezoelectric laminated bodies were prepared in the same manner to perform film formation as in Example 1 except that the introduced gas and the mixing ratio of the base layer were changed to conditions shown in Table 1.

### Examples 7 to 10

In Examples 7 to 10, a Si substrate in which thermal oxide films having a film thickness of 1 μm were formed on surfaces on both sides was used as the substrate. A size of the substrate was 100 mm×100 mm×0.675 mmt. In addition, piezoelectric laminated bodies were prepared in the same manner to perform film formation as in Example 1 except that the introduced gas and the mixing ratio of the base layer were changed to conditions shown in Table 1.

### Examples 11 to 17

In Examples 11 to 17, piezoelectric laminated bodies were prepared in the same manner to perform film formation as in Example 1 except that the film thickness of the base layer was changed to conditions shown in Tables 1 and 2.

### Examples 18 to 21

In Examples 18 to 21, piezoelectric laminated bodies were prepared in the same manner to perform film formation as in Example 1 except that the film thickness of the piezoelectric thin film was changed to conditions shown in Table 2.

### Example 22

In Example 22, a piezoelectric laminated body was prepared in the same manner to perform film formation as in Example 1 except that the introduced gas of the base layer was changed to argon only.

### Example 23

In Example 23, a Si substrate in which thermal oxide films were formed on both surfaces was used as the substrate. A size of the substrate was 100 mm×100 mm×0.675 mmt. Further, a piezoelectric laminated body was prepared in the same manner to perform film formation as in Example 1 except that the introduced gas of the base layer was changed to argon only.

### Examples 24 to 26

In Examples 24 to 26, piezoelectric laminated bodies were prepared in the same manner to perform film formation as in Example 1 except that the base layer was not formed and the film thickness of the piezoelectric thin film was changed to conditions shown in Table 2.

### Example 27

In Example 6, niobium nitride (NbN_{X}) was formed as the base layer. A piezoelectric laminated body was prepared in the same manner to perform film formation as in Example 1 except that Nb metal was used as a target material and a power usage was changed to 500 W in the formation of the base layer

### Example 28

In Example 28, titanium nitride (TiN_{X}) was formed as the base layer. A piezoelectric laminated body was prepared in the same manner to perform film formation as in Example 1 except that Ti metal was used as a target material and a power usage was changed to 500 W in the formation of the base layer.

### Evaluation

The following measurements and evaluations were performed on each of the obtained piezoelectric laminated bodies.

### (Crystallinity of Piezoelectric Thin Film)

For an XRD measurement, an X-ray diffraction device (MiniFlex II, manufactured by Rigaku Corporation) was used. A sample was set so as to evaluate diffraction in a direction perpendicular to the substrate, and a 2θ/θ scan was performed with a divergence slit of 1.25°, a scattering slit of 1.25°, and a light receiving slit of 0.3 mm in a 20 range of 30° to 60°.

After a background correction was performed, the orientation was evaluated by calculating a peak intensity ratio of {(101) plane/(002) plane} based on a ratio of a diffraction intensity of a (002) plane appearing in 2θ=350 to 370 to a diffraction intensity of a (101) plane appearing in 2θ=370 to 390 of an AlN crystal.

The peak intensity ratio of (101) plane/(002) plane was evaluated on five levels. When the level was 2 or more, it was determined that orientation was possible. Results are shown in “c-axis orientation (level)” included in “Piezoelectric thin film (aluminum nitride)” in Tables 1 and 2.
Level 1: more than 0.25 and 1.0 or less
Level 2: more than 0.10 and 0.25 or less
Level 3: more than 0.05 and 0.10 or less
Level 4: more than 0.01 and 0.05 or less
Level 5: 0.01 or less

### (Arithmetic Average Roughness of Piezoelectric Thin Film Surface)

The arithmetic average roughness (Ra) of the piezoelectric thin film was measured with an atomic force microscope (AFM).

A definition of the arithmetic average roughness (Ra) conforms to JIS B 0601-2001.

When the arithmetic average roughness (Ra) is 5.5 nm or less, it can be determined that good flatness was obtained, and when the arithmetic average roughness is 4 nm or less, it can be determined that better flatness was obtained. Results are shown in “Arithmetic average roughness Ra (nm)” included in “Piezoelectric thin film (aluminum nitride)” in Tables 1 and 2.

Device: model number: S-Image, manufactured by SII Nano Technology

### (Nitriding Degree x)

The “nitriding degree x” of the base layer was calculated based on a “refractive index n” by the following method. Hereinafter, description will be made.

First, for use as a reference, under each of the following conditions of a “film formation condition 1” and a “film formation condition 2”, a 20 nm base layer 1 and a 20 nm base layer 2 were formed, respectively.
Base layer 1: film formation condition 1, 700 W of power usage, Ar: 40 sccm, N₂: 10 sccm, film formation pressure: 0.37 Pa
Base layer 2: film formation condition 2, 700 W of power usage, Ar: 0 sccm, N₂: 40 sccm, film formation pressure: 0.35 Pa

For the base layer 1 and the base layer 2, an element ratio of Zr and N in zirconium nitride constituting a crystallinity-improving layer, that is, a value of the nitriding degree x in ZrN_{X} was determined by Rutherford backscattering spectrometry (RBS) (RBS device, manufactured by Kobe Steel, Ltd.) for quantitative determination.

### (Refractive Index n)

Polarization information was measured at a wavelength of 250 nm to 2,500 nm by using a spectroscopic ellipsometer (M-2000, manufactured by J.A. Woollam). The obtained polarization information was used to perform fitting of an optical model, and a value of the refractive index n at a wavelength of 500 nm was determined.

Results of the nitriding degree x and the refractive index n of the base layer 1 and the base layer 2 were as follows.
Evaluation result of the base layer 1: nitriding degree x=1.02 (evaluated by RBS), refractive index n (wavelength: 500 nm)=1.25
Evaluation result of the base layer 2: nitriding degree x=1.60 (evaluated by RBS), refractive index n (wavelength: 500 nm)=3.82

The following correlation equation was obtained based on the evaluation results of the base layer 1 and the base layer 2.

$$Nitriding degree x ( 1 \leq x \leq 2 ) = 0.2333 \times refractive index n ( wavelength : 500 nm ) + 0.7073$$

For the piezoelectric laminated bodies of Example 1 to Example 28, the refractive index n at a wavelength of 500 nm was measured by the above method, and the nitriding degree x was calculated based on the above correlation equation. Results are shown in “Nitriding degree x” included in “Base layer” in Tables 1 and 2.

TABLE 1

| | | Ex. 1 | Ex. 2 | Ex. 3 | Ex. 4 | Ex. 5 | Ex. 6 | Ex. 7 |
|---|---|---|---|---|---|---|---|---|
| Substrate | | Soda- | Soda- | Soda- | Soda- | Soda- | Soda- | Si |
| | | lime | lime | lime | lime | lime | lime | |
| | | glass | glass | glass | glass | glass | glass | |
| Electrode | Chemical formula | Ti | Ti | Ti | Ti | Ti | Ti | Ti |
| layer | Power usage (W) | 500 | 500 | 500 | 500 | 500 | 500 | 500 |
| | Flow rate of Ar gas (sccm) | 80 | 80 | 80 | 80 | 80 | 80 | 80 |
| | Film formation pressure (Pa) | 0.4 | 0.4 | 0.4 | 0.4 | 0.4 | 0.4 | 0.4 |
| | Film thickness (nm) | 150 | 150 | 150 | 150 | 150 | 150 | 150 |
| Base layer | Chemical formula | ZrNₓ | ZrNₓ | ZrNₓ | ZrNₓ | ZrNₓ | ZrNₓ | ZrNₓ |
| | Refractive index (wavelength: | 3.82 | 1.8 | 2.5 | 3.91 | 3.96 | 1.2 | 1.8 |
| | 500 nm) | | | | | | | |
| | Nitriding degree x | 1.6 | 1.13 | 1.29 | 1.62 | 1.63 | 1 | 1.13 |
| | Film thickness (nm) | 10 | 10 | 10 | 10 | 10 | 10 | 10 |
| | Power usage (W) | 700 | 700 | 700 | 700 | 700 | 700 | 700 |
| | Film formation pressure (Pa) | 0.4 | 0.4 | 0.4 | 0.6 | 0.8 | 0.4 | 0.4 |
| | Flow rate of nitrogen gas | 80 | 20 | 40 | 120 | 200 | 11 | 20 |
| | (sccm) | | | | | | | |
| | Flow rate of Ar gas (sccm) | 0 | 60 | 40 | 0 | 0 | 69 | 60 |
| | Flow rate ratio: N₂/(Ar + N₂) | 1 | 0.25 | 0.5 | 1 | 1 | 0.14 | 0.25 |
| Piezoelectric | Power usage (W) | 1,000 | 1,000 | 1,000 | 1,000 | 1,000 | 1,000 | 1,000 |
| thin film | Film formation pressure (Pa) | 0.4 | 0.4 | 0.4 | 0.4 | 0.4 | 0.4 | 0.4 |
| (Aluminum | Flow rate of nitrogen gas | 40 | 40 | 40 | 40 | 40 | 40 | 40 |
| nitride) | (sccm) | | | | | | | |
| | Flow rate of Ar gas (sccm) | 40 | 40 | 40 | 40 | 40 | 40 | 40 |
| | Film thickness (μm) | 1 | 1 | 1 | 1 | 1 | 1 | 1 |
| | Arithmetic average roughness | 1.5 | 1.8 | 1.9 | 1.7 | 1.5 | 4.8 | 3.5 |
| | Ra (nm) | | | | | | | |
| | c-axis orientation (level) | 5 | 3 | 4 | 5 | 5 | 2 | 3 |
| | | Ex. 8 | Ex. 9 | Ex. 10 | Ex. 11 | Ex. 12 | Ex. 13 | Ex. 14 |
| Substrate | | Si | Si | Si | Soda- | Soda- | Soda- | Soda- |
| | | | | | lime | lime | lime | lime |
| | | | | | glass | glass | glass | glass |
| Electrode | Chemical formula | Ti | Ti | Ti | Ti | Ti | Ti | Ti |
| layer | Power usage (W) | 500 | 500 | 500 | 500 | 500 | 500 | 500 |
| | Flow rate of Ar gas (sccm) | 80 | 80 | 80 | 80 | 80 | 80 | 80 |
| | Film formation pressure (Pa) | 0.4 | 0.4 | 0.4 | 0.4 | 0.4 | 0.4 | 0.4 |
| | Film thickness (nm) | 150 | 150 | 150 | 150 | 150 | 150 | 150 |
| Base layer | Chemical formula | ZrNₓ | ZrNₓ | ZrNₓ | ZrNₓ | ZrNₓ | ZrNₓ | ZrNₓ |
| | Refractive index (wavelength: | 2.5 | 3.82 | 1.2 | 3.82 | 3.82 | 3.82 | 3.82 |
| | 500 nm) | | | | | | | |
| | Nitriding degree x | 1.29 | 1.6 | 1 | 1.6 | 1.6 | 1.6 | 1.6 |
| | Film thickness (nm) | 10 | 10 | 10 | 0.2 | 0.4 | 1.25 | 10 |
| | Power usage (W) | 700 | 700 | 700 | 700 | 700 | 700 | 700 |
| | Film formation pressure (Pa) | 0.4 | 0.4 | 0.4 | 0.4 | 0.4 | 0.4 | 0.4 |
| | Flow rate of nitrogen gas | 40 | 80 | 11 | 80 | 80 | 80 | 80 |
| | (sccm) | | | | | | | |
| | Flow rate of Ar gas (sccm) | 40 | 0 | 69 | 0 | 0 | 0 | 0 |
| | Flow rate ratio: N₂/(Ar + N₂) | 0.5 | 1 | 0.14 | 1 | 1 | 1 | 1 |
| Piezoelectric | Power usage (W) | 1,000 | 1,000 | 1,000 | 1,000 | 1,000 | 1,000 | 1,000 |
| thin film | Film formation pressure (Pa) | 0.4 | 0.4 | 0.4 | 0.4 | 0.4 | 0.4 | 0.4 |
| (Aluminum | Flow rate of nitrogen gas | 40 | 40 | 40 | 40 | 40 | 40 | 40 |
| nitride) | (sccm) | | | | | | | |
| | Flow rate of Ar gas (sccm) | 40 | 40 | 40 | 40 | 40 | 40 | 40 |
| | Film thickness (μm) | 1 | 1 | 1 | 1 | 1 | 1 | 1 |
| | Arithmetic average roughness | 1.9 | 1.5 | 5.2 | 2.0 | 1.5 | 1.9 | 1.9 |
| | Ra (nm) | | | | | | | |
| | c-axis orientation (level) | 3 | 5 | 2 | 3 | 5 | 5 | 5 |

TABLE 2

| | | Ex. 15 | Ex. 16 | Ex. 17 | Ex. 18 | Ex. 19 | Ex. 20 | Ex. 21 |
|---|---|---|---|---|---|---|---|---|
| Substrate | | Soda- | Soda- | Soda- | Soda- | Soda- | Soda- | Soda- |
| | | lime | lime | lime | lime | lime | lime | lime |
| | | glass | glass | glass | glass | glass | glass | glass |
| Electrode | Chemical formula | Ti | Ti | Ti | Ti | Ti | Ti | Ti |
| layer | Power usage (W) | 500 | 500 | 500 | 500 | 500 | 500 | 500 |
| | Flow rate of Ar gas (sccm) | 80 | 80 | 80 | 80 | 80 | 80 | 80 |
| | Film formation pressure (Pa) | 0.4 | 0.4 | 0.4 | 0.4 | 0.4 | 0.4 | 0.4 |
| | Film thickness (nm) | 150 | 150 | 150 | 150 | 150 | 150 | 150 |
| Base layer | Chemical formula | ZrNₓ | ZrNₓ | ZrNₓ | ZrNₓ | ZrNₓ | ZrNₓ | ZrNₓ |
| | Refractive index | 3.82 | 3.82 | 3.82 | 3.82 | 3.82 | 3.82 | 3.82 |
| | (wavelength: 500 nm) | | | | | | | |
| | Nitriding degree x | 1.6 | 1.6 | 1.6 | 1.6 | 1.6 | 1.6 | 1.6 |
| | Film thickness (nm) | 20 | 35 | 50 | 10 | 10 | 10 | 10 |
| | Power usage (W) | 700 | 700 | 700 | 700 | 700 | 700 | 700 |
| | Film formation pressure (Pa) | 0.4 | 0.4 | 0.4 | 0.4 | 0.4 | 0.4 | 0.4 |
| | Flow rate of nitrogen gas | 80 | 80 | 80 | 80 | 80 | 80 | 80 |
| | (sccm) | | | | | | | |
| | Flow rate of Ar gas (sccm) | 0 | 0 | 0 | 0 | 0 | 0 | 0 |
| | Flow rate ratio: N₂/(Ar + N₂) | 1 | 1 | 1 | 1 | 1 | 1 | 1 |
| Piezoelectric | Power usage (W) | 1,000 | 1,000 | 1,000 | 1,000 | 1,000 | 1,000 | 1,000 |
| thin film | Film formation pressure (Pa) | 0.4 | 0.4 | 0.4 | 0.4 | 0.4 | 0.4 | 0.4 |
| (Aluminum | Flow rate of nitrogen gas | 40 | 40 | 40 | 40 | 40 | 40 | 40 |
| nitride) | (sccm) | | | | | | | |
| | Flow rate of Ar gas (sccm) | 40 | 40 | 40 | 40 | 40 | 40 | 40 |
| | Film thickness (μm) | 1 | 1 | 1 | 0.1 | 0.25 | 0.5 | 3 |
| | Arithmetic average | 1.7 | 3.5 | 4.8 | 1.2 | 1.6 | 1.8 | 2.4 |
| | roughness Ra (nm) | | | | | | | |
| | c-axis orientation (level) | 5 | 3 | 2 | 3 | 4 | 5 | 5 |

| | | Ex. 22 | Ex. 23 | Ex. 24 | Ex. 25 | Ex. 26 | Ex. 27 | Ex. 28 |
|---|---|---|---|---|---|---|---|---|
| Substrate | | Soda- | Si | Soda- | Soda- | Soda- | Soda- | Soda- |
| | | lime | | lime | lime | lime | lime | lime |
| | | glass | | glass | glass | glass | glass | glass |
| Electrode | Chemical formula | Ti | Ti | Ti | Ti | Ti | Ti | Ti |
| layer | Power usage (W) | 500 | 500 | 500 | 500 | 500 | 500 | 500 |
| | Flow rate of Ar gas (sccm) | 80 | 80 | 80 | 80 | 80 | 80 | 80 |
| | Film formation pressure (Pa) | 0.4 | 0.4 | 0.4 | 0.4 | 0.4 | 0.4 | 0.4 |
| | Film thickness (nm) | 150 | 150 | 150 | 150 | 150 | 150 | 150 |
| Base layer | Chemical formula | Zr | Zr | | | | NbNₓ | TiNₓ |
| | Refractive index | | | | | | | |
| | (wavelength: 500 nm) | | | | | | | |
| | Nitriding degree x | 0 | 0 | | | | 1.6 | 1.6 |
| | Film thickness (nm) | 10 | 10 | | | | 10 | 10 |
| | Power usage (W) | 700 | 700 | | | | 500 | 500 |
| | Film formation pressure (Pa) | 0.4 | 0.4 | | | | 0.4 | 0.4 |
| | Flow rate of nitrogen gas | 0 | 0 | | | | 80 | 80 |
| | (sccm) | | | | | | | |
| | Flow rate of Ar gas (sccm) | 80 | 80 | | | | 0 | 0 |
| | Flow rate ratio: N₂/(Ar + N₂) | 0 | 0 | | | | 1 | 1 |
| Piezoelectric | Power usage (W) | 1,000 | 1,000 | 1,000 | 1,000 | 1,000 | 1,000 | 1,000 |
| thin film | Film formation pressure (Pa) | 0.4 | 0.4 | 0.4 | 0.4 | 0.4 | 0.4 | 0.4 |
| (Aluminum | Flow rate of nitrogen gas | 40 | 40 | 40 | 40 | 40 | 40 | 40 |
| nitride) | (sccm) | | | | | | | |
| | Flow rate of Ar gas (sccm) | 40 | 40 | 40 | 40 | 40 | 40 | 40 |
| | Film thickness (μm) | 1 | 1 | 1 | 0.1 | 3 | 1 | 1 |
| | Arithmetic average | 6.5 | 6.3 | 6.5 | 3.1 | O.R. | O.R. | 4.9 |
| | roughness Ra (nm) | | | | | | | |
| | c-axis orientation (level) | 1 | 1 | 1 | 1 | 1 | 1 | 1 |

### (Dependency of ZrN_{X} on Flow Rate of Nitrogen Gas)

Examples 1 to 6 in Tables 1 and 2 show results when the nitriding degree x of ZrN_{X} was controlled by changing the flow rate of nitrogen gas at the time of forming the base layer in a case where the substrate was soda-lime glass. In addition, Examples 7 to 10 show the same results as in the case where the substrate was a Si substrate. Results of the orientation in the c-axis direction estimated based on the peak intensity ratio obtained by the XRD measurement of the piezoelectric thin film made of AlN having a film thickness of 1 μm in this case, and the arithmetic average roughness (Ra) obtained by the AFM were also shown.

Based on these results, it is understood that when the nitriding degree x is 1.13 to 1.63, the arithmetic average roughness (Ra) is 4 nm or less, the peak intensity ratio of {(101) plane/(002) plane} is 0.25 or less, that is, level 2 or higher, and a piezoelectric laminated body having a good surface shape and excellent orientation is obtained.

On the other hand, in a case where the base layer was Zr as in Examples 22 and 23, in a case where no base layer was inserted as in Examples 24 to 26, and in a case where the base layer was a metal nitride such as NbN or TiN as in Examples 27 and 28, the peak intensity ratio of {(101) plane/(002) plane} was more than 0.25, that is, level 1, and a c-axis oriented piezoelectric laminated body was not obtained. In addition, a film having a relatively large arithmetic average roughness was obtained. “O.R” (over range) in the arithmetic average roughness of Examples 26 and 27 in Table 2 indicates that the evaluation could not be performed properly.

Examples 11 to 17 in Tables 1 and 2 show results of, the orientation in the c-axis direction estimated based on the peak intensity ratio obtained by the XRD measurement of the piezoelectric thin film made of AlN having a film thickness of 1 μm when the film thickness of the ZrN_{X} film as the base layer was changed between 0.2 nm and 50 nm, and the arithmetic average roughness (Ra) obtained by the AFM.

When the film thickness of ZrN_{X} was 0.2 nm or more and 40 nm or less, the arithmetic average roughness (Ra) was 4 nm or less, and the peak intensity ratio of {(101) plane/(002) plane} was 0.25 or less. In particular, it is understood that when the film thickness of ZrN_{X} is 0.4 nm or more and 20 nm or less, the peak intensity ratio of {(101) plane/(002) plane} is 0.01 or less, and a piezoelectric laminated body having a good surface shape and excellent orientation was obtained.

In addition, Examples 18 to 21 in Table 2 show results of: the orientation in the c-axis direction estimated based on the peak intensity ratio obtained by the XRD measurement when, the ZrN_{X} film as the base layer was set to satisfy that the nitriding degree x=1.6 and the film thickness was 10 nm, and the film thickness of AlN was changed; and the arithmetic average roughness (Ra) obtained by the AFM. It is understood that when the film thickness of the ZrN_{X} film is in a range of 100 nm to 3 μm, the arithmetic average roughness (Ra) is 4 nm or less, the peak intensity ratio of {(101) plane/(002) plane} is 0.25 or less, and a piezoelectric laminated body having a good surface shape and excellent orientation is obtained. On the other hand, in Examples 24 to 26 in which no base film was provided, it was confirmed that sufficient orientation was not obtained and cracks were generated in a region where the piezoelectric thin film made of AlN was thick.

Finally, Examples 27 and 28 in Table 2 show results of, the orientation in the c-axis direction estimated based on the peak intensity ratio obtained by the XRD measurement of the piezoelectric thin film made of AlN having a film thickness of 1 μm when NbN_{X} and TiN_{X} were provided as base layers other than ZrN_{X} as the base layer, and the arithmetic average roughness (Ra) obtained by the AFM. In Examples 27 and 28, the peak intensity ratio of {(101) plane/(002) plane} is 0.25 or more, indicating that sufficient orientation was not obtained. It is understood that, although ZrNₓ, NbNₓ, and TiNₓ, which are materials constituting the base layer, are each treated equivalently as a transition metal nitride in many cases, in the piezoelectric laminated body according to the present embodiment, a specific effect is obtained by adopting zirconium nitride for the base layer.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2022-080483) filed on May 16, 2022, the content of which is incorporated herein by reference.

### REFERENCE SIGNS LIST

100: piezoelectric laminated body
101: substrate
102: electrode layer
103: base layer
104: piezoelectric thin film
105: laminated film

1. A piezoelectric laminated body comprising:
a substrate; and
a laminated film provided on at least one surface of the substrate, wherein
the laminated film comprises an electrode layer, a base layer, and a piezoelectric thin film in this order from a substrate side,
the base layer and the piezoelectric thin film are in contact with each other,
the base layer contains zirconium nitride, and
the piezoelectric thin film has a hexagonal wurtzite structure oriented in a c-axis direction.

2. The piezoelectric laminated body according to claim 1, wherein
the piezoelectric thin film contains aluminum nitride, and
the aluminum nitride has the hexagonal wurtzite structure oriented in the c-axis direction.

3. The piezoelectric laminated body according to claim 1, wherein
the zirconium nitride is represented by a chemical formula ZrN_{X}, and a nitriding degree represented by x in the chemical formula is in a range of 1<x<2.

4. The piezoelectric laminated body according to claim 3, wherein
the nitriding degree is in a range of 1.1<x<1.65.

5. The piezoelectric laminated body according to claim 1, wherein
a thickness of the base layer is 0.2 nm or more and 40 nm or less.

6. The piezoelectric laminated body according to claim 5, wherein
the thickness of the base layer is 0.4 nm or more and 20 nm or less.

7. The piezoelectric laminated body according to claim 1, wherein
an arithmetic average roughness (Ra) of the piezoelectric thin film is 4.0 nm or less.

8. The piezoelectric laminated body according to claim 1, wherein
a ratio {(101) plane/(002) plane} of a peak intensity of a (101) plane to a peak intensity of a (002) plane in an X-ray diffraction pattern of the piezoelectric thin film measured by an out-of-plane method is 0.25 or less.

9. The piezoelectric laminated body according to claim 1, wherein
a ratio {(101) plane/(002) plane} of a peak intensity of a (101) plane to a peak intensity of a (002) plane in an X-ray diffraction pattern of the piezoelectric thin film measured by an out-of-plane method is 0.1 or less.

10. The piezoelectric laminated body according to claim 1, wherein
a film thickness of the piezoelectric thin film is 100 nm or more and 10 μm or less.

11. A piezoelectric element comprising the piezoelectric laminated body according to claim 1.

12. A method for manufacturing a piezoelectric laminated body comprising a substrate and a laminated film provided on at least one surface of the substrate, the method comprising:
preparing the substrate; and
forming an electrode layer, a base layer, and a piezoelectric thin film on the at least one surface of the substrate in this order, wherein
the base layer contains zirconium nitride,
the piezoelectric thin film has a hexagonal wurtzite structure oriented in a c-axis direction, and
the piezoelectric thin film is formed so as to be in contact with the base layer.

13. The method for manufacturing a piezoelectric laminated body according to claim 12, wherein
the piezoelectric thin film contains aluminum nitride, and
the aluminum nitride has the hexagonal wurtzite structure oriented in the c-axis direction.

14. The method for manufacturing a piezoelectric laminated body according to claim 12, wherein
a film formation is performed by a sputtering method.
